(19) United States
(12) Patent Application Publication
(10) Pub. No.: US 2020/0091062 A1
(43) Pub. Date: Mar. 19, 2020

(54) INTEGRATED CIRCUIT CAVITY FORMATION WITH MULTIPLE INTERCONNECTION PADS

(71) Applicant: QUALCOMM Incorporated, San Diego, CA (US)

(72) Inventors: Jaehyun YEON, San Diego, CA (US); Hong Bok WE, San Diego, CA (US); Chin-Kwan KIM, San Diego, CA (US); Kuiwon KANG, San Diego, CA (US)

(21) Appl. No.: 16/131,224

(22) Filed: Sep. 14, 2018

(51) Int. Cl. H01L 23/498; H01L 23/538; H01L 23/00; H01L 21/68; H05K 1/11; H05K 1/18; H05K 3/46

(52) U.S. Cl. CPC H01L 23/49855; H01L 23/5383; H01L 23/5384; H01L 23/5385; H01L 23/5389; H05K 3/4602; H01L 24/24; H01L 24/82; H01L 21/681; H05K 1/117; H05K 1/185; H01L 24/32

(57) ABSTRACT

Certain aspects of the present disclosure provide techniques for forming a cavity with various conductive pad interconnections for receiving an electronic component in an integrated circuit. One example method of fabricating an integrated circuit generally includes forming a conductive metal above a first substrate layer, forming a barrier metal above the conductive metal, disposing at least one second substrate layer above the barrier metal, forming a cavity in the at least one second substrate layer by using a laser to expose the barrier metal and the conductive metal in the cavity, and etching the conductive metal in the form of a conductive pad pattern for coupling the conductive metal to an electronic component.

### BACKGROUND

### Field of the Disclosure

Aspects of the present disclosure relate to integrated circuits, and more particularly, to techniques for forming a cavity with various conductive pad interconnections in an integrated circuit for receiving an electronic component.

### Description of Related Art

The continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Most of the semiconductor devices that are at this time being created are aimed at processing digital data. There are however also numerous semiconductor designs that are aimed at incorporating analog functions into devices that simultaneously process digital and analog data, or devices that can be used for the processing of only analog data.

### BRIEF SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include improved methods for forming a cavity with various conductive pad interconnections in an integrated circuit.

Certain aspects provide a method of fabricating an integrated circuit. The method generally includes forming a conductive metal above a first substrate layer, forming a barrier metal above the conductive metal, disposing at least one second substrate layer above the barrier metal, forming a cavity in the at least one second substrate layer by using a laser to expose the barrier metal and the conductive metal in the cavity, and etching the conductive metal in the form of a conductive pad pattern for coupling the conductive metal to an electronic component.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 is a flow diagram of example operations for fabricating an integrated circuit having a cavity as described herein, in accordance with certain aspects of the present disclosure.

FIG. 2A illustrates a cross-sectional view of an example core substrate, in accordance with certain aspects of the present disclosure.

FIG. 2B illustrates a cross-sectional view of the core substrate with a pattern and plating applied, in accordance with certain aspects of the present disclosure.

FIG. 2C illustrates a cross-sectional view of the core substrate with a barrier metal mask applied, in accordance with certain aspects of the present disclosure.

FIG. 2D illustrates a cross-sectional view of the core substrate with a barrier metal formed on a conductive pad, in accordance with certain aspects of the present disclosure.

FIG. 2E illustrates a cross-sectional view of the core substrate with the barrier metal mask removed, in accordance with certain aspects of the present disclosure.

FIG. 2F illustrates a cross-sectional view of a lamination of other substrate layers on the example core substrate, in accordance with certain aspects of the present disclosure.

FIG. 2G illustrates a cross-sectional view of applying a solder resist to the laminated substrates, in accordance with certain aspects of the present disclosure.

FIG. 2H illustrates a cross-sectional view of forming a cavity in the laminated substrate using a laser, in accordance with certain aspects of the present disclosure.

FIG. 2I illustrates a cross-sectional view of etching a conductive pad pattern in the cavity, in accordance with certain aspects of the present disclosure.

FIG. 2J illustrates a cross-sectional view of disposing a device in the cavity, in accordance with certain aspects of the present disclosure.

FIG. 3A illustrates a cross-sectional view of an example conductive pad separated from a sidewall of the cavity, in accordance with certain aspects of the present disclosure.

FIG. 3B illustrates a cross-sectional view of an example conductive pad engaged with a sidewall of the cavity, in accordance with certain aspects of the present disclosure.

FIG. 4A illustrates a top view of an example conductive pad having a single contact in a cavity, the conductive pad being separated from a sidewall of the cavity, in accordance with certain aspects of the present disclosure.

FIG. 4B illustrates a top view of an example conductive pad having a single contact in a cavity, the conductive pad being engaged with a sidewall of the cavity, in accordance with certain aspects of the present disclosure.

FIG. 4C illustrates a top view of an example conductive pad having two contacts in a cavity, the conductive pad being separated from a sidewall of the cavity, in accordance with certain aspects of the present disclosure.

FIG. 4D illustrates a top view of an example conductive pad having two contacts in a cavity, the conductive pad being engaged with a sidewall of the cavity, in accordance with certain aspects of the present disclosure.

FIG. 4E illustrates a top view of an example conductive pad having four contacts in a cavity, the conductive pad being separated from a sidewall of the cavity, in accordance with certain aspects of the present disclosure.

FIG. 4F illustrates a top view of an example conductive pad having four contacts in a cavity, the conductive pad being engaged with a sidewall of the cavity, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Aspects of the present disclosure provide techniques for forming a cavity with various conductive pad interconnections in an integrated circuit, the cavity for receiving an electronic component, such as an inductor or other passive component.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

### Example Integrated Circuit Cavity Formation with Multiple Interconnection Pads

To reduce the height of an integrated circuit (IC) and thereby assist in the miniaturization of such semiconductor devices, some relatively large electronic components (such as inductive elements or other passive components) are disposed in a cavity of the integrated circuit and coupled to one or more conductive pads inside the cavity. Some difficulties may be encountered when forming the conductive pad(s) inside the cavity. For example, dielectric materials below the conductive pad(s) can be damaged while using a laser ablation method to form the cavity. Damages to the dielectric materials could result in reliability issues, such as a failure during a biased highly accelerated stress test (BHAST). As another example, the dielectric material may not be fully removed while forming the cavity using a chemical etching process. This may result in a tapered sidewall of the cavity, which does not allow for a deep cavity to receive the device. A chemical etching process may also leave some dielectric material on the conductive pads, which may interfere with the electrical connection between the electrical component disposed in the cavity and the conductive pad.

Certain aspects of the present disclosure provide techniques for forming a conductive pad in a cavity using a metal barrier above the conductive metal, which forms the conductive pad. The metal barrier may serve as a mask for the chemical etching process. This enables the conductive metal to also serve as a mask for the laser ablation method. Thus, the operation of forming the conductive pad in the cavity may be performed using the laser ablation method followed by the chemical etching process as further described herein.

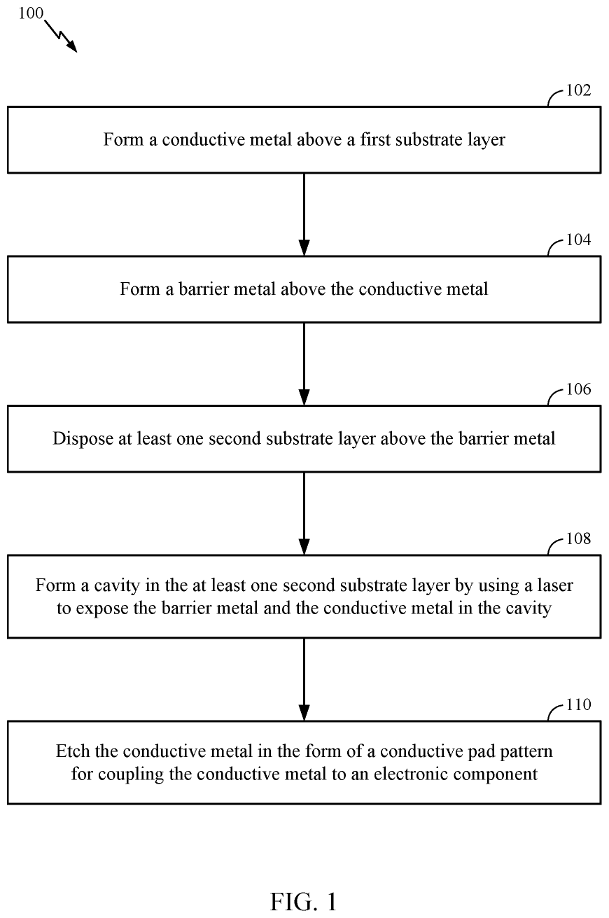

FIG. 1 is a flow diagram of example operations 100 for forming one or more conductive pads in a cavity of an integrated circuit, in accordance with certain aspects of the present disclosure. The operations 100 may begin, at block 102, where a conductive metal is formed above a first substrate layer (e.g., a core substrate material or a coreless substrate layer). At block 104, a barrier metal is formed above the conductive metal. At block 106, at least one second substrate layer is disposed above the barrier metal. At block 108, a cavity is formed in the at least one second substrate layer by using a laser to expose the barrier metal and the conductive metal in the cavity. At block 110, the conductive metal (at least in the cavity) is etched in the form of a conductive pad pattern for coupling the conductive metal to an electronic component.

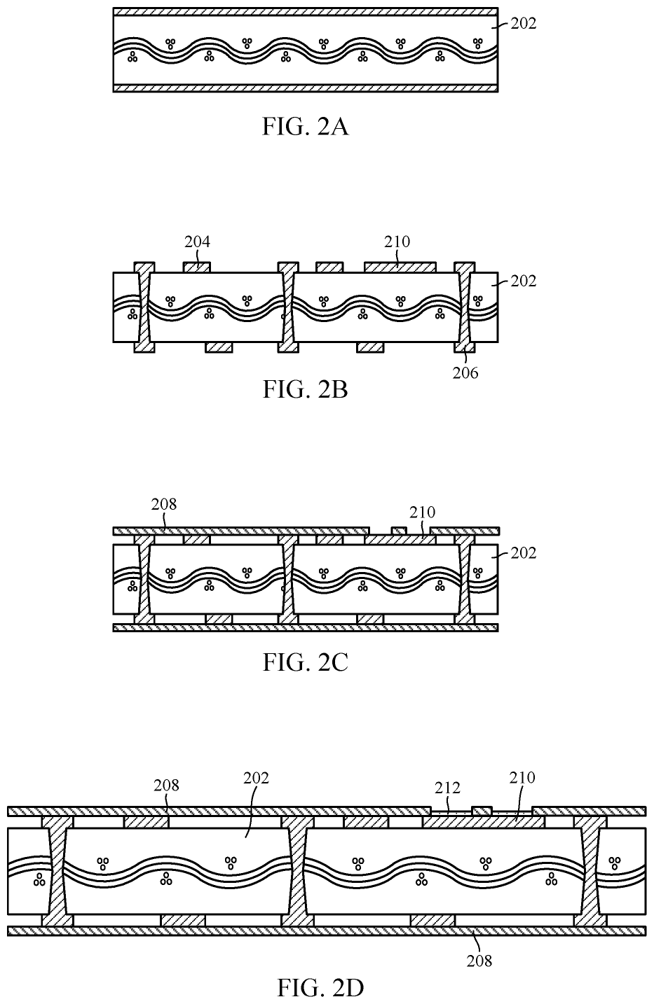

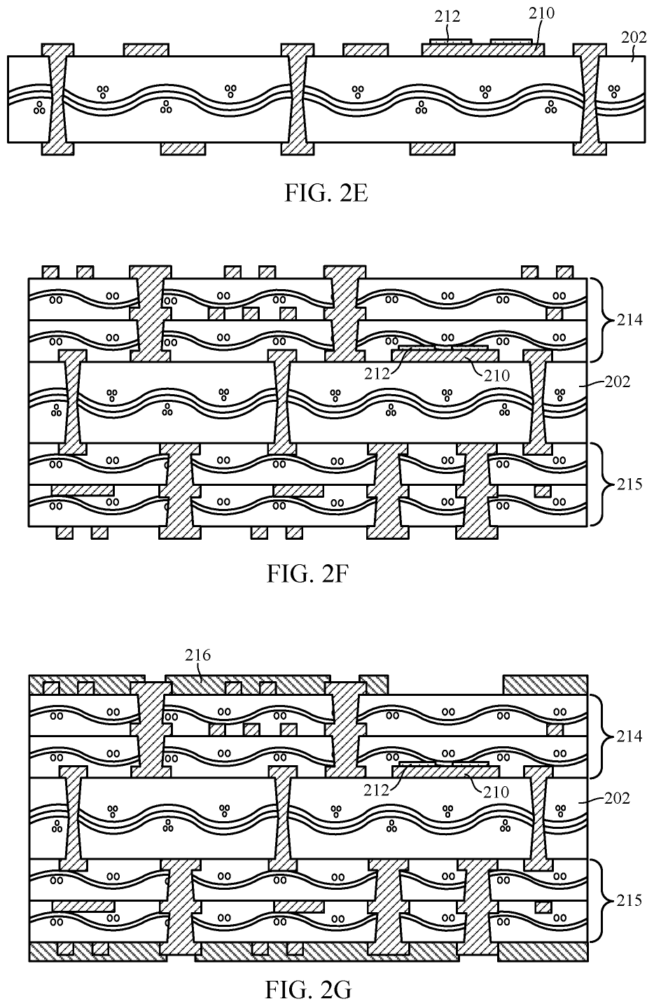

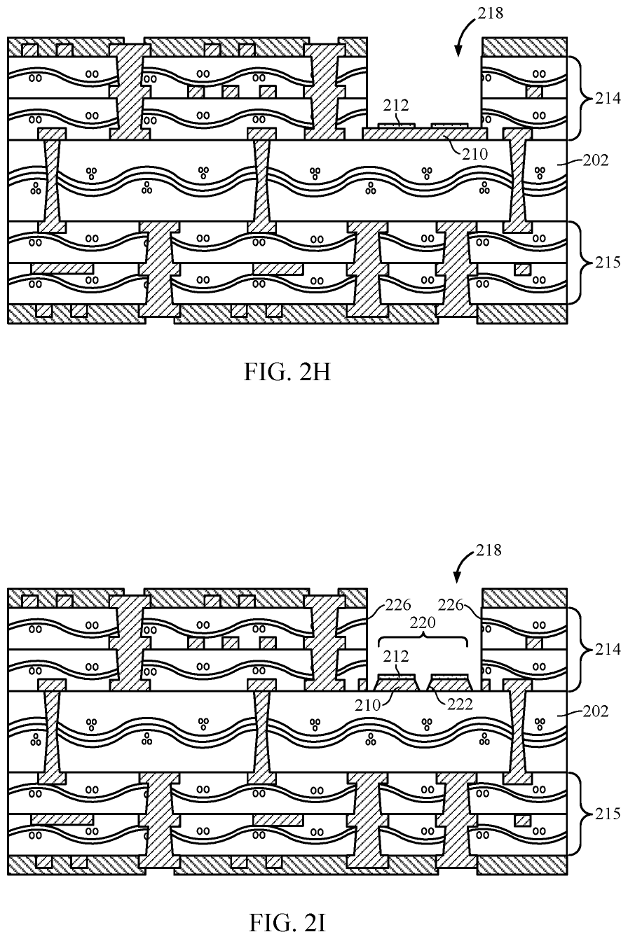

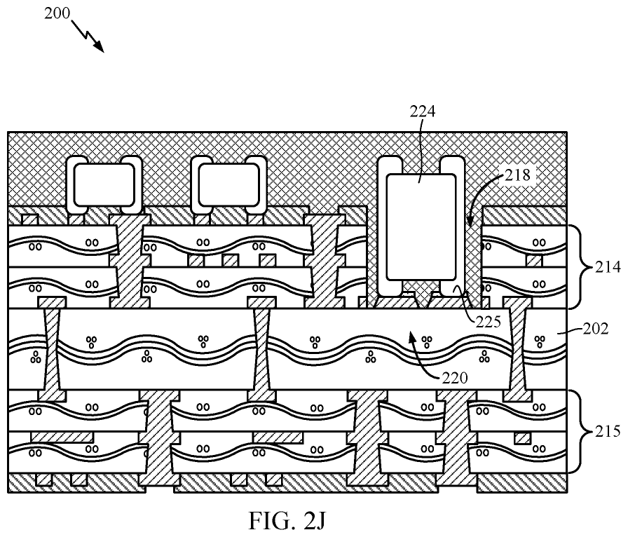

FIGS. 2A-2J are cross-sectional views showing example operations for forming a conductive pad in a cavity of an example integrated circuit, in accordance with certain aspects of the present disclosure. As shown in these example operations, the first substrate layer may be a core substrate material having laminated substrate layers thereon. In other aspects, the cavity may be formed, as described herein, in an embedded trace substrate (ETS) material or a coreless laminate of substrate materials.

Referring to FIG. 2A, a first substrate layer 202 is formed. The first substrate layer 202 may be a core substrate layer or a coreless substrate layer. As shown in FIG. 2B, patterning of conductive trace(s) 204 and via(s) 206 may be performed on the first substrate layer 202. In this example, the conductive metal 210, which forms a portion of the conductive pad in the cavity as further described herein, may also be patterned above the first substrate layer 202. The conductive metal 210 may be deposited above the first substrate layer using any process that grows, coats, or otherwise transfers the conductive metal 210 above the first substrate layer 202, such as physical vapor deposition (PVD), chemical vapor deposition (CVD), electrochemical deposition (e.g., electroplating), molecular-beam epitaxy (MBE), or atomic layer deposition (ALD). The conductive metal 210 may be any suitable conductive metal or metal alloy, such as copper or a copper alloy. The conductive metal 210 may also include a masking material for laser etching as further described herein.

Referring to FIG. 2C, a mask 208 may be formed above the first substrate layer, the conductive metal 210, the trace(s) 204, and the via(s) 206. The mask 208 may be a photoresist mask that is applied above the first substrate layer 202. The mask 208 may provide a pattern for depositing a barrier metal 212 above the conductive metal 210 as shown in FIG. 2D. For example, a metallic material may be deposited according to the pattern of the photoresist mask to form the barrier metal 212. In certain aspects, forming the barrier metal 212 may include depositing the barrier metal 212 in a pattern that forms a mask for a plurality of conductive pads during a subsequent chemical etching process (e.g., at block 110 of FIG. 1).

Referring to FIG. 2E, the mask 208 may be removed using, for example, an etching process, leaving the barrier metal 212 above the conductive metal 210 in a pattern that forms the conductive pads in the cavity as further described herein. The barrier metal 212 may be any suitable conductive metal or metal alloy that is resistant to chemical etching. For example, the barrier metal 212 may include at least one of nickel (Ni), gold (Au), tungsten (W), or chromium (Cr). The barrier metal 212 may serve as a masking material for chemical etching as further described herein.

As shown in FIG. 2F, at least one second substrate layer 214 may be disposed above the barrier metal 212, the conductive metal 210, and the first substrate layer 202. In this example, the at least one second substrate layer 214 includes two additional substrate layers formed above the first substrate layer 202. For certain aspects, at least one third substrate layer 215 may be disposed below the first substrate layer. As illustrated in FIG. 2F, the at least one third substrate layer may include two substrate layers formed below the first substrate layer 202. Referring to FIG. 2G, a layer of solder resist 216 may be disposed above the at least one second substrate layer 214.

In FIG. 2H, the cavity 218 is formed in the at least one second substrate layer 214 by using a laser to expose the barrier metal 212 and the conductive metal 210 in the cavity 218. In some aspects, using the laser to form the cavity may include performing laser drilling with the laser to remove a portion of the at least one second substrate layer 214. The barrier metal 212 and conductive metal 210 may span the bottom of the cavity 218 to prevent the laser ablation method from damaging the first substrate layer 202.

Referring to FIG. 2I, the conductive metal 210 is etched to form a conductive pad pattern. The barrier metal 212 may serve as a mask for the conductive pad pattern to allow removal of portions of the conductive metal 210 during the etching process (e.g., a chemical etching process), but prevent the removal of portions of the conductive metal 210 directly underneath the barrier metal 212. The conductive pad pattern may provide a plurality of conductive pads for coupling to an electronic component. In some aspects, the conductive pad pattern may also provide conductive pads for coupling the conductive metal 210 and barrier metal 212 to vias and/or conductive traces embedded in or disposed on a surface of the first substrate layer 202 and/or the at least one second substrate layer 214.

In this example, the conductive metal 210 and the barrier metal 212 may form multiple conductive pads 220 in the cavity 218 that are separated from the sidewalls 226 of the cavity 218. As shown, at least one of the conductive pads 220 may have at least one tapered edge 222 of the conductive metal 210. The conductive pads 220 may be electrically coupled to vias and/or conductive traces embedded in or disposed on a surface of the first substrate layer 202 and/or the at least one second substrate layer 214.

In FIG. 2J, an electronic component 224 may be disposed in the cavity 218 and coupled to the conductive pads 220. More specifically, terminals 225 (e.g., a leadframe) of the electronic component 224 may be coupled to the conductive pads 220, via any of various suitable techniques including solder reflow. As shown, the cavity 218 is formed in an integrated circuit 200 without any damage to the first substrate layer 202 below the conductive pads 220 caused by laser etching the cavity. The conductive pads 220 also do not have any residual dielectric material on them left from the chemical etching process.

The electronic component 224 may be any suitable passive component such as an inductor. The depth of the cavity 218 may be selected relative to the height of the electronic component, such that when the electronic component 224 is disposed in the cavity 218, the height of the integrated circuit 200 is within a threshold height from the surface of the integrated circuit (e.g., flush with the height of the integrated circuit).

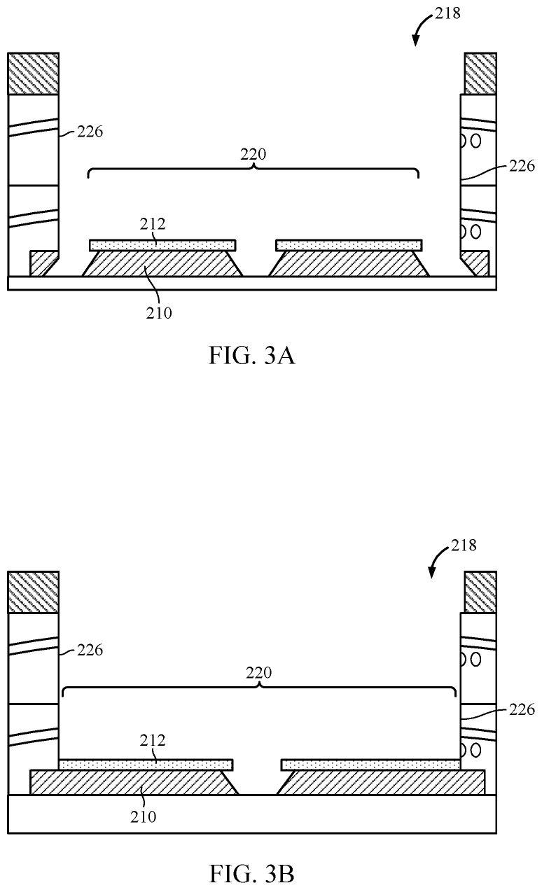

In aspects, the conductive pad pattern may take various shapes. For example, FIGS. 3A and 3B illustrate cross-sectional views of example conductive pads 220, in accordance with certain aspects of the present disclosure. Referring to FIG. 3A, the conductive pad pattern may have an undercut of the conductive metal 210 relative to the barrier metal 212. That is, the conductive metal 210 may be recessed relative to the barrier metal 212. The conductor pads 220 may also be separated from the sidewall 226 of the cavity 218. This may enable the conductor pads 220 to be electrically insulated from the sidewall 226 of the cavity 218. As shown in FIG. 3B, the conductor pads 220 may be engaged with (e.g., contact or be at least partially embedded in) the sidewall of the cavity 218. This may enable the conductor pads 220 to be electrically coupled to traces or vias embedded in the sidewall of the cavity 218.

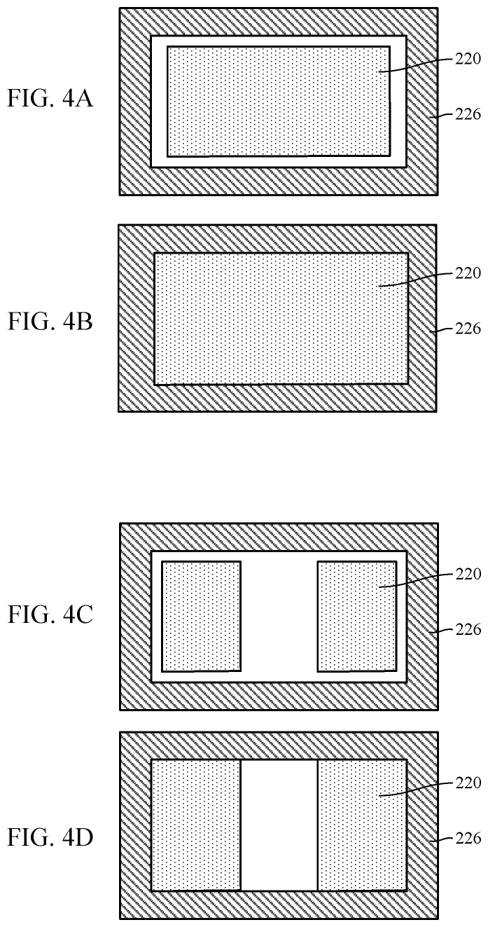

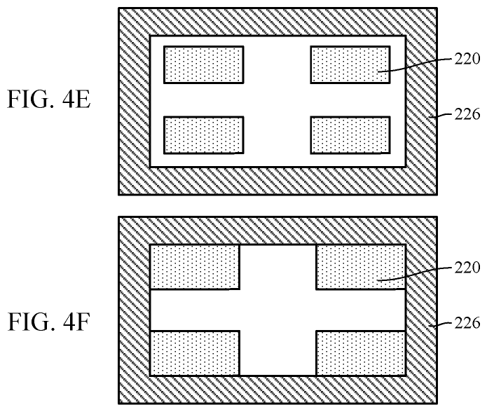

FIGS. 4A-4F illustrate top views of various conductive pad shapes, in accordance with certain aspects of the present disclosure. For some aspects, the conductive pad pattern may provide a single conductive pad. For example, FIG. 4A shows a single conductive pad 220 separated from the sidewall 226. In other aspects, the single conductive pad 220 may be engaged with sidewall 226 as shown in FIG. 4B.

In aspects, the conductive pad pattern may provide a plurality of conductive pads in the cavity for coupling to the electronic component. For example, FIG. 4C shows two conductive pads 220 separated from the sidewall 226 of the cavity, whereas in FIG. 4D, the two conductive pads 220 partially engage with the sidewall 226. Referring to FIG. 4E, the conductive pad pattern has four conductive pads 220 separated from the sidewall 226, and in FIG. 4F, there are four conductive pads 220 that partially engage with the sidewall 226.

The operations for forming the conductive pad pattern in the cavity described herein provide various improvements over using either the laser ablation method or chemical etching process for such formation. For instance, the operations described herein may enable a reduction in the height of the integrated circuit including complex circuit modules and a system-in-package (SIP). The operations described herein reduce or prevent damage to the dielectric material between conductive pads inside the cavity. The operations described herein may also enable improved interconnection yield and/or reliability by providing a residue-free pad. The operations described herein may also enable electrical performance gains as the electronic component can be placed closer to internal traces within the integrated circuit, thereby reducing parasitics (e.g., parasitic capacitance).

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

It is to be understood that the claims are not limited to the precise configuration and components illustrated above. Various modifications, changes and variations may be made in the arrangement, operation and details of the methods and apparatus described above without departing from the scope of the claims.

1. A method of fabricating an integrated circuit, comprising:
forming a conductive metal above a first substrate layer;
forming a barrier metal above the conductive metal;
disposing at least one second substrate layer above the barrier metal;
forming a cavity in the at least one second substrate layer by using a laser to expose the barrier metal and the conductive metal in the cavity; and
etching the conductive metal in the form of a conductive pad pattern for coupling the conductive metal to an electronic component.

2. The method of claim 1, wherein etching the conductive metal comprises chemical etching the conductive metal.

3. The method of claim 2, wherein the barrier metal is a masking material for the chemical etching.

4. The method of claim 1, wherein the barrier metal comprises at least one of nickel, gold, tungsten, or chromium.

5. The method of claim 1, wherein forming the barrier metal comprises:
applying a photoresist mask above the first substrate layer, the photoresist mask having a pattern;
depositing a metallic material according to the pattern of the photoresist mask to form the barrier metal; and
removing the photoresist mask to leave the barrier metal.

6. The method of claim 1, wherein the conductive metal comprises copper.

7. The method of claim 1, wherein the conductive metal is a masking material for laser etching.

8. The method of claim 1, wherein the conductive pad pattern comprises an undercut of the conductive metal relative to the barrier metal.

9. The method of claim 1, wherein the conductive pad pattern comprises at least one tapered edge of the conductive metal.

10. The method of claim 1, wherein a wall of the cavity contacts a portion of the conductive pad pattern.

11. The method of claim 1, wherein a wall of the cavity is separated from the conductive pad pattern.

12. The method of claim 1, wherein the conductive pad pattern comprises a plurality of conductive pads for coupling to the electronic component.

13. The method of claim 12, wherein forming the barrier metal comprises depositing the barrier metal in a pattern that forms a mask for the plurality of conductive pads.

14. The method of claim 12, further comprising:
disposing the electronic component in the cavity; and
coupling terminals of the electronic component to the plurality of conductive pads.

15. The method of claim 1, wherein the first substrate layer and the at least one second substrate layer form an embedded trace substrate material.

16. The method of claim 1, wherein the first substrate layer and the at least one second substrate layer form a coreless laminate of substrate materials.

17. The method of claim 1, wherein using the laser comprises performing laser drilling.
